(19) United States
(12) Patent Application Publication
(10) Pub. No.: US 2026/0219305 A1
(43) Pub. Date: Jul. 30, 2026

(54) ELECTRIC METER WITH DETECTION SYSTEM

(71) Applicant: Greentec International Limited, Lichfield Staffordshire (GB)

(72) Inventor: Matthew Hunt, Lichfield Staffordshire (GB)

(73) Assignee: Greentec International Limited, Lichfield Staffordshire (GB)

(21) Appl. No.: 19/148,671

(22) PCT Filed: Jan. 8, 2024
(86) PCT No.: PCT/GB2024/050027

§ 371 Date: Jul. 16, 2025

(30) Foreign Application Priority Data
Jan. 17, 2023 (GB) 2300667.9

(51) Int. Cl. G01R 22/06; G01R 19/165; G01R 23/00; H02H 3/20

(52) U.S. Cl. CPC G01R 22/063; G01R 19/16576; G01R 23/005; H02H 3/20

(57) ABSTRACT

Aspects of the invention relate to an electric meter (100), a system (606), and a method (800). The electric meter (100) comprises a metering engine (116) to detect electrical energy consumption. The electric meter (100) comprises a detection system (104). The detection system (104) is configured to create a star point (127) from phases (L1, L2, L3) from a multi-phase power source (1). The detection system (104) is configured to measure a voltage between the star point and a neutral conductor or an earth conductor. The detection system (104) is configured to transmit an output signal in dependence on the voltage exceeding a threshold.

### FIELD OF THE INVENTION

Embodiments of the present invention relate to an electric meter with a detection system. In particular, but not exclusively, they relate to an electric meter comprising a metering engine to detect electrical energy consumption, and comprising a detection system.

### BACKGROUND TO THE INVENTION

An electric meter is a device to measure the total electrical power consumed over a time interval, generally for billing and monitoring purposes.

If a three-phase electrical power source is available from the electricity supply network, the electric meter will receive three live phases L1, L2, L3 each carried by a separate phase conductor. Depending on the earthing system, the electric meter may also receive a neutral conductor N, or separate neutral N and earth conductors E (PE, Protective Earth), or a combined protective earth and neutral (PEN) conductor.

Depending on the electrical distribution network, an earthing system of the three-phase electrical power source may either be TN (terra-neutral) or TT (terra-terra) as defined in IEC 60364. Note: In the United States and Canada, ‘earth’ is referred to as ‘ground’.

In a TN-type earthing system, the earth connection is provided by the electricity supply network. A TN-type earthing system is effective, provided that the neutral conductor is functioning. If the neutral conductor is broken on the supply side, there is no longer a reference voltage for the three phases. If the load between phases is unbalanced (which it invariably is because there will be different loads on each phase), the voltage between phases can become substantial, causing a potential electrocution or fire risk through the neutral conductor at the customer side. Residual Current Devices (RCDs, also known as Ground Fault Interrupters, GFIs) would not be able to detect the break if the earthing system is TN-C-S (terra-neutral combined-separated). An RCD will not detect an open neutral event as the live and neutral are still balanced even though the earth conductor may be live.

Further, regardless of earthing system, earth electrodes can degrade over time, or earth potential can vary. If a neutral conductor breaks while the local earth electrode is disconnected or has a high resistance, an RCD may not work so an electric shock or fire risk may still arise.

### BRIEF DESCRIPTION OF VARIOUS EMBODIMENTS OF THE INVENTION

According to various, but not necessarily examples of the disclosure, there is provided an electric meter comprising a metering engine to detect electrical energy consumption, and comprising a detection system, wherein the detection system is configured to:
create a star point from phases from a multi-phase power source;
measure a voltage between the star point and a neutral conductor or an earth conductor; and
transmit an output signal in dependence on the voltage exceeding a threshold.

According to various, but not necessarily examples of the disclosure, there is provided a system comprising a plurality of devices, each device having one of the detection system, and at least one of the devices being an electric meter, wherein an upstream device of the plurality of devices is upstream of a plurality of branch circuits, wherein downstream devices of the plurality of devices are in respective ones of the branch circuits, and wherein a destination and/or instruction of the output signal associated with each detection system is dependent on which one of the devices detects the voltage exceeding a threshold.

According to various, but not necessarily examples of the disclosure, there is provided a method of monitoring an electrical fault, the method comprising:
measuring, at an electric meter, a voltage between a star point created from phases of a multi-phase power source, and either a neutral conductor or an earth conductor; and
transmitting an output signal in dependence on the voltage exceeding a threshold.

According to various, but not necessarily examples of the disclosure, there is provided a detection system configured to:
create a star point from phases from a multi-phase power source;
measure a voltage between the star point and a neutral conductor or an earth conductor;
transmit a first output signal in dependence on the voltage exceeding a threshold;
measure a frequency of at least one of the phases, by frequency measuring circuitry of the detection system; and
transmit a second output signal in dependence on the frequency exceeding an upper frequency threshold greater than a nominal grid frequency and/or in dependence on the frequency passing below a lower frequency threshold less than the nominal grid frequency.

According to various, but not necessarily examples of the disclosure, there is provided a method comprising:
measuring a voltage between a star point created from phases of a multi-phase power source, and either a neutral conductor or an earth conductor;
transmitting a first output signal in dependence on the voltage exceeding a threshold;
measuring a frequency of at least one of the phases; and
transmitting a second output signal in dependence on the frequency exceeding an upper frequency threshold greater than a nominal grid frequency and/or in dependence on the frequency passing below a lower frequency threshold less than the nominal grid frequency.

### BRIEF DESCRIPTION OF THE DRAWINGS

For a better understanding of various examples of embodiments of the present invention reference will now be made by way of example only to the accompanying drawings in which: FIG. 1 illustrates an example of an electric meter, a distribution board, and a load;

FIGS. 2A-2B illustrate phasor diagrams for a three-phase star system in balanced and unbalanced states, respectively;

FIG. 3 illustrates an example electric meter;

FIG. 4 illustrates an example controller;

FIG. 5 illustrates an example of a non-transitory computer-readable storage medium;

FIG. 6 illustrates a first example of a detection system;

FIG. 7 illustrates a second example of a detection system;

FIGS. 8A-8C illustrate examples of systems comprising a plurality of devices;

FIG. 9 illustrates an example of a system for a branched electrical supply;

FIG. 10 is a flowchart illustrating an example method; and

FIG. 11 is a flowchart illustrating an example method.

### DETAILED DESCRIPTION OF VARIOUS EMBODIMENTS OF THE INVENTION

FIG. 1 illustrates a multi-phase power source 1 in the form of a three-phase electrical supply, at the interface to a customer premises. The input of an electric meter 100 (‘meter’ herein) is connected to conductors L1, L2, L3, N.

The three-phase power source 1 comprises three phases, represented by conductors, L1, L2, L3. They are connected to an input of the meter 100. In the United States of America, the conductors L1-L3 may be referred to as A, B, C.

Away from the premises, the three phases L1, L2, L3 are connected to a supply transformer (not shown) and a remote earth electrode (not shown).

The supply transformer may connect the phase conductors L1, L2, L3 in a star configuration, also referred to as a Wye configuration.

The remote earth electrode is a supply earth electrode, tens of meters to kilometers away from the meter 100. The remote earth electrode can comprise an earth rod, for example.

The centre of the star configuration of the supply transformer is earthed via a remote earth conductor, connecting the centre of the star configuration of the supply transformer to the remote earth electrode.

The three-phase power source 1 further comprises a neutral conductor N connected to the meter 100. The neutral conductor N is connected to the centre of the star configuration of the supply transformer. The neutral conductor N is therefore connected to the remote earth conductor.

FIG. 1 shows that no separate earth conductor connects the remote earth electrode/supply transformer to the meter 100/premises. In the specific example of FIG. 1, but not necessarily in all examples, the neutral conductor N (e.g., PEN conductor) splits at an electrical intake position of the premises into a separate neutral conductor N and earth conductor E. In other words, the earthing system shown is TN-C-S. Embodiments of the invention are applicable to different earthing systems than that shown. The ‘electrical intake position’ refers to the electrical equipment where electricity enters the premises, and comprises a fuse, meter, and distribution board. The electrical intake position is the interface between supply side and customer side.

The output of the meter 100 is connected to a distribution board 200, for example via a set of cables referred to in some territories as ‘meter tails’ as defined in relevant IEE regulations. Meter tails are generally less than three metres long, to avoid the need for an additional protective device.

In other examples, the meter 100 is housed with the distribution board 200 in a common housing, together defining a system comprising a distribution board 200 and a meter 100.

The distribution board 200 for a premises is referred to as a breaker (US) or consumer unit (UK). The distribution board 200 comprises busbars to divide the incoming supply into one or more branch circuits. For illustrative purposes, no branches are shown in FIG. 1.

Different branch circuits are connected to different loads in the premises. FIG. 1 shows a load 300 connected to the sole branch from the distribution board 200. Loads can comprise any appropriate equipment.

Different branch circuits can comprise different numbers of phases. For example, one branch circuit can be three-phase while another can be single-phase.

A three-phase branch circuit can be used to supply high voltage/three-phase loads 300 such as industrial refrigeration units, three-phase induction motors, and industrial equipment. The illustrated load 300 receives L1, L2, L3, N, and E conductors.

The distribution board 200 can comprise one or more automatic circuit breakers such as RCDs (GFIs). An automatic circuit breaker may be installed in the distribution board 200 for each branch circuit. In the event of a detected fault in a branch circuit, the RCD disconnects the individual branch circuit while the other branch circuits remain closed-circuit.

The distribution board 200 of FIG. 1 is further connected to a local earth electrode 202. The local earth electrode 202 can be a dedicated earth rod/pad, or an existing earthed component such as an electrically conductive gas or water pipe.

The illustrated distribution board 200 receives L1, L2, L3, N and an earth conductor E. The earth and neutral conductors E, N are split from a PEN conductor at an electrical intake position comprising the meter 100A and distribution board 200. The distribution board 200 is locally connected/bonded to earth, and outputs separate earth and neutral conductors E, N for each branch circuit. The separate earth and neutral conductors are linked together at the distribution board 200.

In other examples, the distribution board 200 does not output a separate earth conductor and the load 300 may be earthed locally to the load 300.

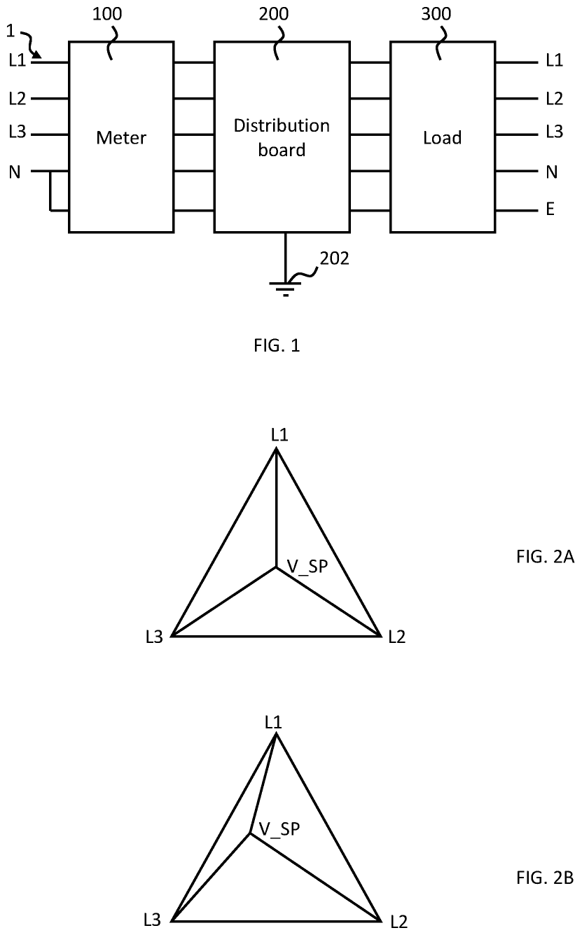

FIGS. 2A-2B illustrate phasor diagrams of a three-phase star system in balanced and unbalanced states, respectively.

FIG. 2A represents the star in a balanced configuration. Each phase L1, L2, L3 has an equal voltage, such as 230V. The centre of the star point has a voltage V_SP of zero volts and is shown in the centre of the triangle between the phases L1, L2, L3.

FIG. 2B represents the star in an unbalanced configuration. The phases L1, L2, L3 have unequal voltages. As a result, the star point has changed position within the triangle, to an off-centre position. This represents an elevated voltage V_SP seen at the star point.

If the neutral conductor is intact, then the voltage V_SP will not be substantially elevated as a result of L1, L2, L3 being unbalanced. Therefore, the neutral conductor N will not carry elevated voltages.

As will be described, it is possible to calculate the voltage of the star point by either creating a physical star circuit, or via calculation after individually measuring the voltages of L1, L2,

L3. In accordance with aspects of the invention, the meter 100 is provided with a detection system to create a star point and calculate voltages based on the star point. This provides the ability to detect a neutral fault and/or an earth fault at the meter 100.

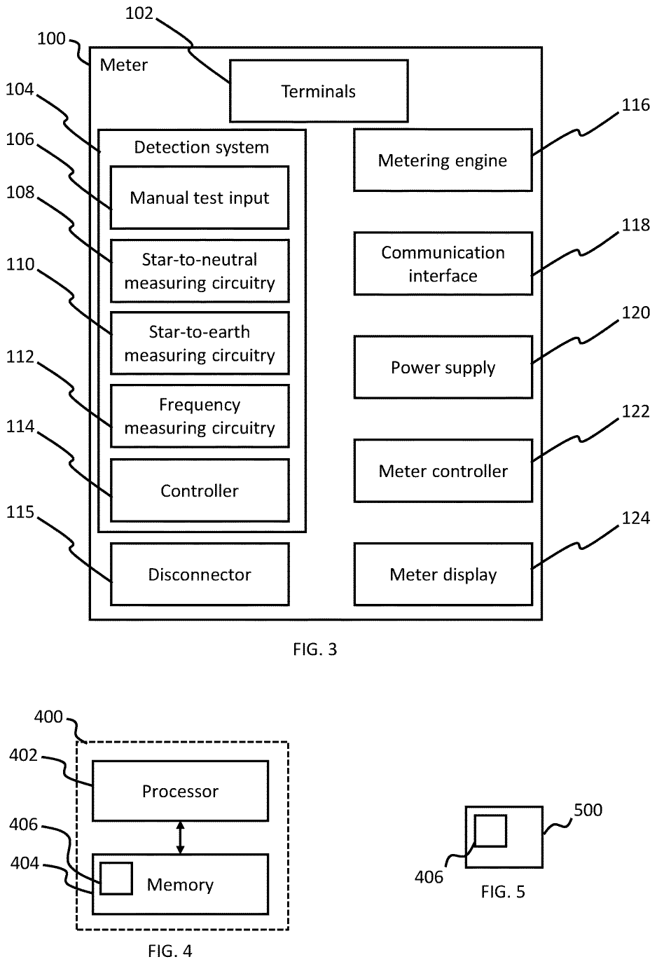

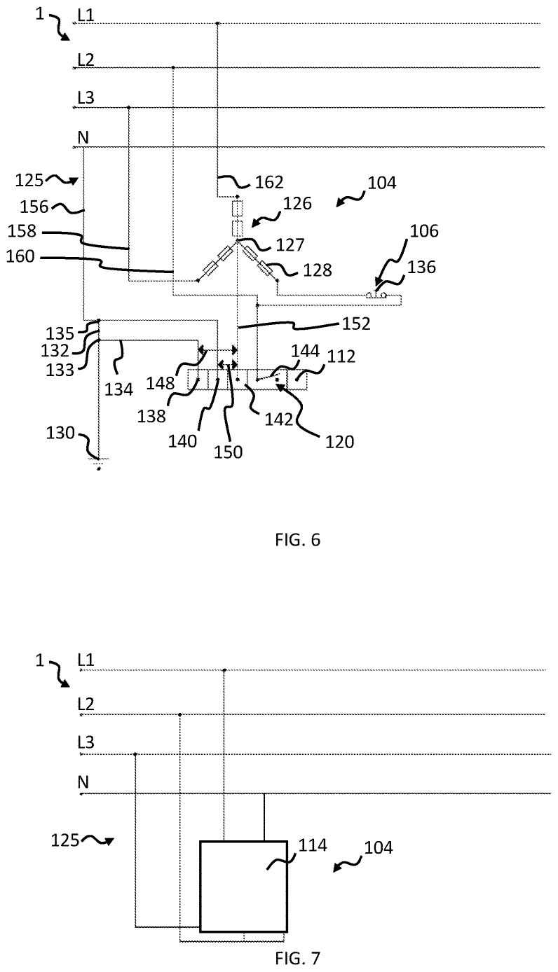

FIG. 3 is a functional block diagram schematically illustrating the components of a meter 100 incorporating a detection system 104. FIGS. 6 and 7 are circuit diagrams of the detection system 104.

Implementing the detection system 104 in a meter 100 is advantageous because meters 100 are generally located at the interface between supply side and customer side, upstream of the distribution board 200. A single detection system 104 in the meter 100 can therefore detect upstream (supply side) open neutral faults. Therefore, it may be immediately evident that the fault is the responsibility of a distribution network operator (DNO) rather than the customer. A further advantage is that existing componentry in the meter 100 can be shared with the detection system 104.

With reference to FIGS. 3, 6, and 7, the detection system 104 is described first.

The illustrated detection system 104 comprises star-to-neutral measuring circuitry 108, star-to-earth measuring circuitry 110, and frequency measuring circuitry 112.

As shown in FIG. 6, the detection system 104 is configured to create a star point 127 from the three-phase power source 1. The detection system 104 comprises a detection branch 125 divided from the power source 1 being measured, and a star point 127 in the detection branch 125.

The detection branch 125 comprises three branch phase conductors 158, 160, 162, each one connected to an individual one of the three live conductors (phases L1, L2, L3). The detection branch 125 further comprises a branch neutral conductor 156 connected to the neutral conductor N of the three-phase power source 1.

The star point 127 is created by a circuit which ties the three branch phase conductors 158, 160, 162 together to form a star 126. This creates a star point 127 at the centre of the star 126. Ends of the phase conductors are tied together to form the star point 127. The star point 127 is without reference to the neutral conductor N, and is therefore defined as a ‘virtual neutral’ because it is not connected to the neutral conductor N.

The star 126 can comprise a resistor network of resistors 128, or a transformer network. Each arm of the star 126 can comprise one or more resistors 128. The resistors 128 may be configured to provide the same total resistance of each arm. The phase currents cancel each other out at the zero (star) point 127 and create a fixed measurement point with zero current flow. Alternatively, other components may be used such as transformers.

A detection branch 125 for the detection system 104 means that electrical power flowing through the meter 100 does not flow through the detection system 104.

For measurement purposes, the detection system 104 further comprises branch terminals 138, 140, 142 connecting the detection branch 125 to measuring circuitry.

Firstly, the branch terminals comprise an earth terminal 138 to receive an earth measuring conductor 134, as will be described.

Secondly, the branch terminals comprise a neutral terminal 140, wherein the branch neutral conductor 156 is connected to the neutral terminal 140.

Thirdly, the branch terminals comprise a star terminal 142 to receive a star conductor 127. The star conductor 152 connects the star point 127 to the star terminal 142.

The star-to-neutral measuring circuitry 108 is configured to detect a fault condition relating to the neutral conductor N.

As shown in FIG. 6, the star-to-neutral measuring circuitry comprises any appropriate voltage sensor 150 in addition to the conductors 152, 156 and terminals 140, 142. The voltage sensor 150 is configured to measure a voltage between the star point 127 and the neutral conductor N. The voltage sensor 150 is schematically represented by a double-headed arrow in FIG. 6.

FIG. 6 schematically illustrates the voltage sensor 150 being connected to the star terminal 142 and the neutral terminal 140, to measure the voltage therebetween.

If the voltage exceeds a predetermined neutral threshold, the detection system 104 transmits an output signal as will be described later. The voltage sensor 150 may be executed in hardware and/or in software by a controller 114.

The voltage can exceed the neutral threshold if all of the following conditions are simultaneously true: (1) the neutral conductor N is broken; and (2) the load 300 between phases L1, L2, L3 is unbalanced.

In FIG. 6, the meter 100 is connected to a local earth electrode 130, which may be the same as, or different from the earth electrode 202 of FIG. 1. The meter 100 may have a dedicated local earth electrode 130, or may share one with the distribution board 200.

In FIG. 6, the detection system 104 further comprises star-to-earth measuring circuitry 110, configured to detect a fault condition relating to the local earth electrode 130. An advantage of this additional earth check is the ability to check imported voltages from the local earth electrode 130, also referred to as an elevated earth potential. Stray voltages coming into the earth electrode 130 are detectable. Further, the effect of degradation of the connection of the earth electrode to true earth is detectable.

To enable the measurement, the branch terminals of the detection system 104 further include the earth terminal 138 connected to the local earth electrode 130.

As shown in FIG. 6, the star-to-earth measuring circuitry can comprise any appropriate voltage sensor 148 in addition to the conductors 152, 134 and terminals 138, 142. The voltage sensor 148 is schematically represented by a double-headed arrow in FIG. 6. The voltage sensor 148 is configured to measure a voltage between the star point 127 and the local earth electrode 130. FIG. 6 schematically illustrates the voltage sensor 148 being connected to the star terminal 142 and the earth terminal 138, to measure the voltage therebetween.

If the voltage exceeds a predetermined earth threshold, the detection system 104 transmits an output signal as will be described later. The voltage sensor 148 may be executed in hardware and/or in software by a controller 114.

According to the implementation of FIG. 6, the local earth electrode 130 is connected to the earth terminal 138 via a set of conductors. The branch neutral conductor 156 is connected to a branch earth conductor 132 at a junction 135. The branch earth conductor 132 extends to the local earth electrode 130. A connection 133 is provided along the branch earth conductor 132 or at the local earth electrode 130, from which an earth measuring conductor 134 extends. The earth measuring conductor 134 is connected to the earth terminal 138 of the detection system 104.

Referring to FIGS. 3 and 6, a manual test input 106, such as a manual test switch, is provided to cause the star-to-neutral measuring circuitry 108 to register an above-threshold voltage and initiate the transmission of an output signal. The manual test input 106 may further (or separately) cause the star-to-earth measuring circuitry 110 to register an above-threshold voltage and initiate the transmission of an output signal.

One of the branch phase conductors 160 is connected to the star 126 via the manual test input 106. The illustrated manual test input 106 is a hand-operable circuit breaker in the form of a normally closed push button 136. The manual test input 106 is manually operable to cause a loss of one of the three phases at the star 126, in this case L2.

This phase loss will shift the voltage of the star point 127 to the midpoint between the remaining two phases, being 115 volts on a 230-volt system. This would cause the detection system 104 to initiate the disconnection because the voltage is over the relevant threshold. This is an effective way of checking that the system is functional, with minimal components.

FIG. 6 illustrates the branch terminals of the detection system 104 further comprising a power supply 120. The power supply 120 may supply electrical power to the meter 100.

The power supply 120 is connected to one of the phases, in this case L2. FIG. 6 illustrates the power supply 120 comprising a power supply terminal 144 connected to a phase L2 via a branch phase conductor 160. FIG. 6 further illustrates the power supply terminal 144 comprising, or being otherwise connected to, a switch. The switch may be manually and/or automatically actuated.

As shown in FIGS. 3 and 6, the detection 104 can further comprise frequency measuring circuitry 112. This enables a demand response function to be provided. A demand response function is a grid balancing function in which loads are dynamically connected and disconnected to assist with regulating grid frequency within acceptable limits. A good example is controlling a large refrigeration unit, which has a high power demand, but can be switched off for a few hours without significantly affecting the internal temperature.

The frequency measuring circuitry 112 can comprise any appropriate frequency sensor, to detect the frequency of at least one phase, or each phase, of the three-phase power source 1.

Although not shown in FIG. 6, the frequency measuring circuitry 112 can be branched from the three-phase power source 1. For example, the frequency measuring circuitry 112 can be connected to each branch phase conductor 158, 160, 162.

If the measured frequency of a phase leaves a predetermined frequency range (e.g., upper and lower thresholds), the detection system 104 transmits an output signal as will be described later. The frequency sensor may be executed in hardware and/or in software by a controller 114.

The frequency may be measurable by a high degree of accuracy, such as 0.1 Hz, to enable precise thresholds to be defined such as plus or minus 0.5 Hz relative to a target nominal grid frequency.

FIG. 7 illustrates an alternative implementation in which the star point 127 is created in software rather than via circuitry. FIG. 7 illustrates the detection branch 125 being connected to a controller 114 to create the star point 127 in software. The controller 114 may detect the individual voltages of the individual phases, and calculate the star point 127 therefrom.

As shown in FIG. 4, a controller 400 (such as the controller 114) can comprise at least one processor 402; and at least one memory 404 including computer program code 406, the at least one memory 404 and the computer program code 406 (software) configured to, with the at least one processor 402, cause the controller to perform its functions.

By further detecting the voltage of the neutral conductor, the controller 114 can perform the functionality of the star-to-neutral measuring circuitry 108. The controller 114 can monitor the voltage relative to the relevant threshold and transmit the relevant output signal.

By further detecting the voltage of the earth measuring conductor, the controller 114 can perform the functionality of the star-to-earth measuring circuitry 110. The controller 114 can monitor the voltage relative to the relevant threshold and transmit the relevant output signal.

By further detecting the individual phase frequencies, the controller 114 can perform the functionality of the frequency measuring circuitry 112. The controller 114 can monitor the frequency, or frequencies, relative to the relevant range, and transmit the relevant output signal.

Turning back to the meter diagram of FIG. 3, the detection system 104 is schematically represented by the following functional blocks: a manual test input 106; star-to-neutral measuring circuitry 108; star-to-earth measuring circuitry 110; frequency measuring circuitry 112; and a controller 114.

The meter 100 of FIG. 3 further comprises terminals 102. The terminals 102 include input terminals connectable to L1, L2, L3, N at the supply/upstream side, and output terminals connectable to L1, L2, L3, N at the customer/downstream side. The detection branch 125 may be in a path between the input and output terminals. Optionally, the input and/or output terminals are further connectable to an earth conductor.

In some, but not necessarily all examples, the output signal from the detection system 104 is operable to cause disconnection of the three-phase power source 1. Therefore, the meter 100 of FIG. 3 further comprises a disconnector 115 controllable by the output signal from the controller 114. The disconnector 115 is operable to open and close a connection between the input terminals and the output terminals of the terminals 102.

The disconnector 115 in the meter 100 may be located downstream of the detection branch 125, so that the detection branch 125 continues to operate while the output terminals are disconnected. This provides the ability for the detection system 104 to automatically detect that the relevant threshold is no longer exceeded, and reconnect the three-phase power source 1.

In other examples, the disconnector 115 is not part of the meter 100 but is still controllable by the meter 100. For example, a network of remotely-controllable switches may be deployed, each remotely controllable to connect/disconnect a load 300 or circuit branch or transfer the load 300 between phases. For example, a refrigeration unit may have an integrated remotely-controllable switch. Each switch is in operable communication with the meter 100, in-use.

In some examples, the disconnector 115 can be configured for automatic operation. If the meter 100 is connected to earth, the disconnector 115 can be advantageously controlled by two separate actuators configured to switch the disconnector 115 in a predetermined sequence. The actuators may comprise relays. The two actuators may be configured so that the first actuator disconnects the phases L1, L2, L3 prior to the second actuator disconnecting earth. For reconnection, the actuators may be configured so that the second actuator reconnects earth before the first actuator reconnects the phases L1, L2, L3. This ensures that equipment is always earthed when live.

In some examples, the first actuator may be replaced with a set of actuators, each for actuating an individual phase L1, L2, L3.

The sequence may comprise a time separation between initiations of the sequential disconnections.

The meter 100 further comprises a metering engine 116. The metering engine 116 comprises any appropriate analog or digital circuitry to measure electrical power consumption. For example, the metering engine 116 may comprise voltmeters and ammeters.

The meter 100 further comprises a communication interface 118. The communication interface 118 can comprise any appropriate wired or wireless communication interface 118. The communication interface 118 may be configured to send signals and/or information to a remote apparatus as will be described. The communication interface 118 may be configured to send the output signals as described herein.

The communication interface 118 may be configured to communicate with a remote apparatus. The remote apparatus may be separated from the meter 100 by a wide area communication network such as the Internet or a telecommunications network. Alternatively, the separation may be over a local area communication network.

The manner in which the communication interface 118 communicates with the remote apparatus may be via a communications standard, such as short-message-service, or via

Internet Protocol, e-mail, and/or any other appropriate standard. Information from both the metering engine 116 and from the detection system 104 may be sent via the communication interface 118.

The communication interface 118 may comprise a radio frequency transmitter or transceiver. The radio frequency transmitter or transceiver may be operable in a GHz band. The radio frequency transmitter or transceiver may be compatible with wireless local area network standards (e.g., Wi-Fi), wireless personal area network standards (e.g., Bluetooth), and/or wireless telecommunication standards (e.g., 3GPP standards).

In FIG. 3, the meter 100 further comprises a power supply 120. In some examples, the same power supply 120 supplies power to the detection system 104 as well as the metering engine 116.

In FIG. 3, the meter 100 further comprises a meter controller 122. The meter controller 122 may have the architecture shown in FIG. 4. The meter controller 122 may be the same controller as the controller 114 of the detection system 104, or a different controller.

In FIG. 3, the meter 100 further comprises a meter display 124. The meter display 124 may display information dependent on electrical energy consumption detected by the metering engine 116, such as cumulative power consumed. In some examples, the meter display 124 may display information from the detection system 104. In other examples, the meter 100 does not have a local display, instead communicating with a remote display device via the communication interface 118. In further examples, the meter 100 has a local display 124 and can still communicate with a remote display device to control a remote display.

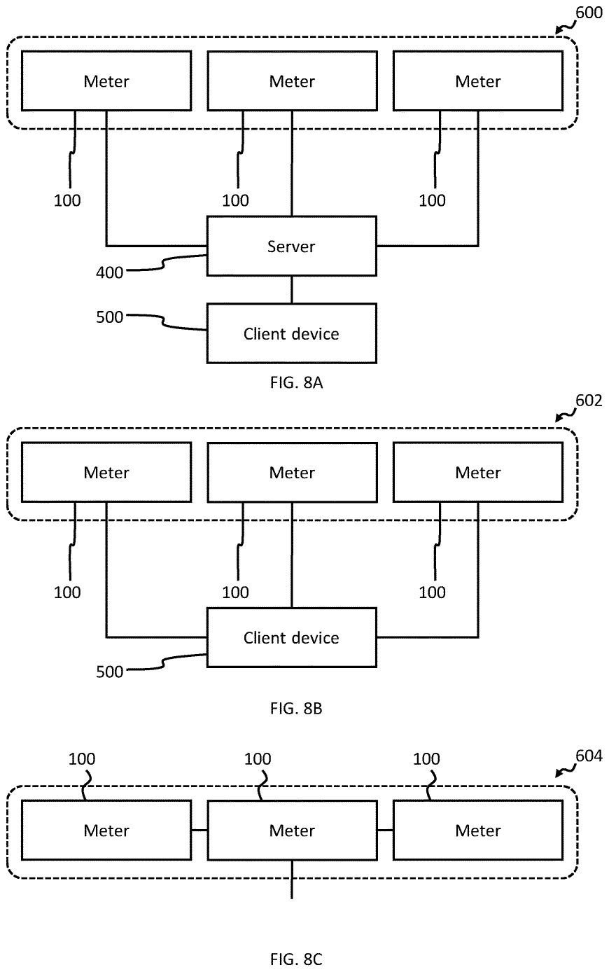

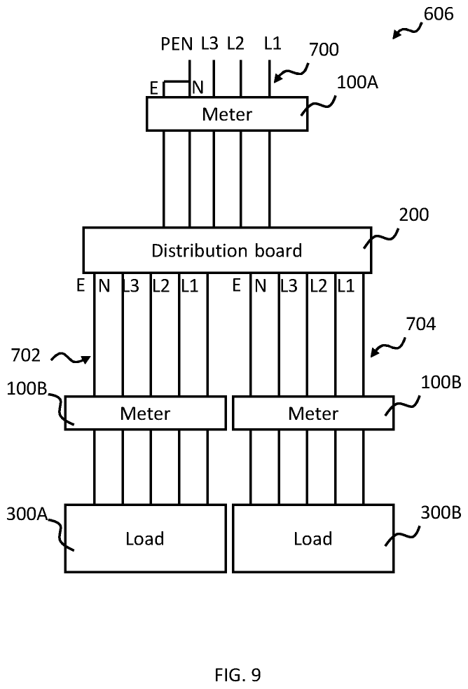

FIGS. 8A-8C illustrate systems 600, 602, 604 depicting different networks that can be formed via meters 100 each having a communication interface 118 as shown in FIG. 3.

In the system 600 of FIG. 8A, each meter 100 is connected to a remote server 400 via their respective communication interface 118. The remote server 400 is operably coupled with a remote client 500 such as a user equipment (UE). The remote client 500 can comprise a computer such as a laptop, phone, or tablet. The remote server 400 may be a single server computer (centralized) or a cloud server (multiple networked server computers).

The remote server 400 may be operable to transmit output signals to devices other than the meters 100. The client device 500 may render alerts or warnings based on the passing of the thresholds described herein. Further, if the disconnectors 115 are separate devices from the meters 100, then the output signal to the disconnector 115 may come either directly from the meter 100 or indirectly via the remote server 400.

An advantage of output signals being directed through the remote server 400 is enabling the provision of ad hoc networks, and additional configurability. For example, a single meter 100 may be configurable to control multiple disconnectors.

The remote server 400 may be configured to store, manage, and/or transmit configuration settings associated with individual meters 100. For example, a configuration setting may indicate which disconnectors 115 are associated with the or each meter 100. Additionally, or alternatively, a configuration setting may indicate the value of any one or more of the monitored thresholds of the detection system 104. Each meter 100 may operate in accordance with a corresponding configuration setting. Each configuration setting may be in the form of software or firmware.

In some examples, telemetry may be sent to the remote server 400 via the communication interface 118. For example, the detection system 104 may be configured to continuously or periodically or conditionally send information dependent on any one of more of the measured voltages and/or the measured frequency or frequencies.

The sent information may be timestamped. The information may comprise diagnostic data. The diagnostic data may indicate a time history of the measured voltages and/or frequencies. The information may be presented graphically to a user of the client device 500. The telemetry may comprise a live feed. Spikes in the voltage difference(s) may be automatically flagged via an appropriate timestamp. Sending telemetry information enables remote inspection of spikes or upwards drift in the voltage differences, where they should be substantially zero.

In the alternative system 602 of FIG. 8B, each meter 100 communicates individually with the remote client device 500 without an intervening server. The client device 500 may embody the above-described features of the remote server 400.

In the system 604 of FIG. 8C, the meters 100 can communicate with each other. For example, one meter 100 can be configured as a master device while the others are configured as slave devices. The master device can communicate with the remote server 400 or client device 500. The slave devices can only communicate with the master device. This facilitates communication over a virtual private network (VPN) and therefore improves data security.

FIG. 9 illustrates an example system 606 comprising a plurality of meters 100A, 100B. A distribution board 200 receives a three-phase power source 700, and outputs two three-phase branch circuits 702, 704 to different loads 300A, 300B.

The system 606 comprises a supply meter 100A upstream of the distribution board 200. The system 606 further comprises a branch meter 100B in each branch circuit. This enables the approximate location of a faulty neutral or faulty earth to be isolated. This also allows separate metering of each branch circuit.

If a fault is detected by a branch meter 100B, then the fault is likely to be isolated to the branch circuit 702 or 704 in which the branch meter 100B is located. If a fault is detected by the supply meter 100A, then the fault may be at the supply side 700 or in either of the branch circuits 702, 704.

The earth measuring conductor 134 of the star-to-earth measuring circuitry 110 of each branch meter 100B may be connected to a local earth electrode 130 and/or to the earth conductor E.

An advantage of FIG. 9 is that the branch meters 100B can be used to individually switch on and off individual branch circuits 702, 704 or loads 300A, 300B, without affecting other branch circuits. This can be useful in a hotel or apartment block, where a fault specific to one floor or dwelling should not cause disruption to other fault-free floors or dwellings.

Although FIGS. 8A-9 illustrate meters 100, it would be appreciated that some of the meters 100, such as the branch meters 100B, may be replaced by detection system devices 104 not having metering functions.

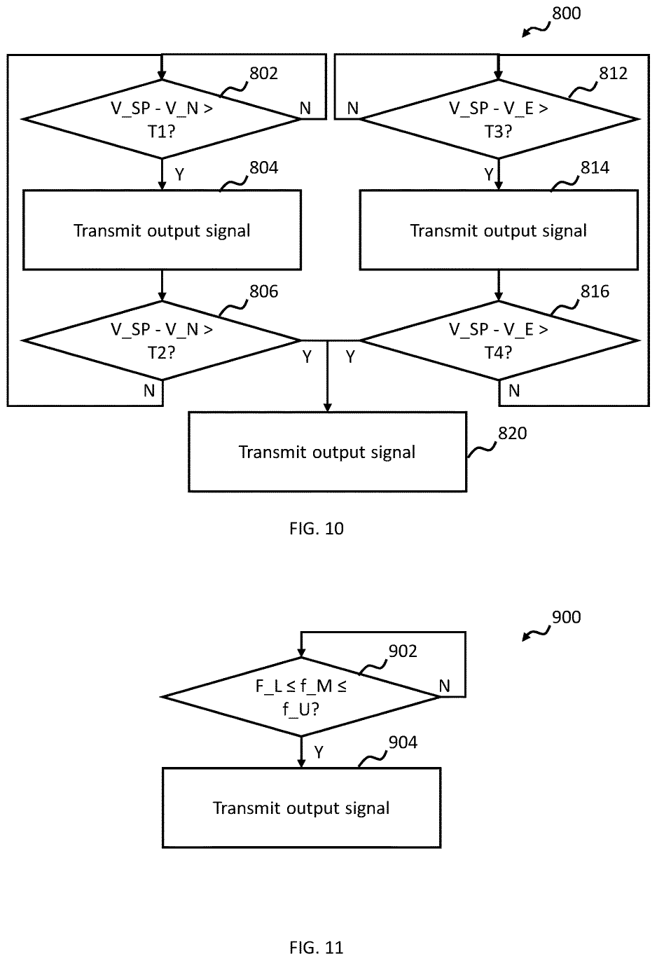

FIG. 10 illustrates a flowchart of a method 800. The method 800 may be implemented by the detection system 104.

The method 800 includes the above-described detection methods for detecting neutral and earth faults, and additional optional blocks. Decision block 802 comprises determining whether a voltage imbalance condition is satisfied, associated with the neutral conductor N. Satisfaction of the voltage imbalance condition depends on the voltage between the star point V_SP and the neutral conductor V_N rising above an imbalance threshold T1. Block 802 may be performed by a controller 114 using the star-to-neutral measuring circuitry 108.

For example, an imbalance threshold may have a value from the range 3 volts to less than volts, such as approximately 5 volts. The value is high enough to indicate a voltage imbalance while being low enough that an actual fault with the neutral conductor N, such as a broken neutral conductor N, is unlikely.

The purpose of the voltage imbalance condition is to provide an energy saving opportunity. If the star point 127 to Neutral voltage exceeds this imbalance threshold (e.g., 5 volts), then a voltage imbalance notification message will be output to show that the phases are not in a balanced state.

The meter 100 will send the voltage imbalance notification message to any appointed recipient. This will then give the recipient the opportunity to reduce loads on phases or transfer loads between phases until the star point to neutral voltage reaches equilibrium (0 volts). Alternatively, the load transfer may be performed automatically as will be described.

If the voltage imbalance condition is satisfied, the method 800 proceeds to block 804 which comprises transmitting an output signal. The controller 114 of the detection system 104 may transmit the output signal.

The output signal may be configured to cause sending of the voltage imbalance notification message. The output signal may be configured to control the communication interface 118 to send the message. The message may be directed to the remote client 500. For example, an e-mail or short message (SMS) may be sent to the remote client 500. Additionally, or alternatively, the output signal may control the meter display 124 to render the message. Additionally, or alternatively, a timestamped flag may be applied to telemetry to indicate when the neutral warning condition was satisfied.

Additionally, or alternatively, an output signal may be transmitted to trigger an audible and/or visual alert via an output device such as a loudspeaker and/or a display such as the meter display 124.

If the load switching/transfer is automatic, block 804 can comprise transmitting an output signal to cause control of individual single-phase loads, to modify relative loading between individual ones of the phases to reduce the voltage detected at block 802. For example, the output signal may be transmitted to a switching system to cause the switching system to connect or disconnect a single-phase load and/or transfer the load between phases.

The switching system can be implemented in various ways, such as a switching device or a network of remotely-controllable switches. The disconnector 115 can comprise the switching system or the switching system may be separate from the disconnector 115. Either way, the switching system enables a given load to be switchable to another phase, and/or enables individual loads powered by a given phase to be individually connectable and disconnectable to that phase.

In some examples, block 804 can comprise transmitting a plurality of output signals, for example to cause the message to be sent and to cause the load switching/transfer.

The next decision block 806 comprises determining whether the voltage between the star point V_SP and the neutral conductor V_N exceeds the neutral threshold T2. Block 806 may be performed by a controller 114 using the star-to-neutral measuring circuitry 108.

In an example implementation, the neutral threshold is in the order of tens of volts, such as more than 30 volts or more than 40 volts. In an implementation, the neutral threshold is approximately 70 volts. The specific threshold value may vary from country to country/grid to grid.

If block 806 is satisfied, the method 800 proceeds to block 820 which comprises transmitting an output signal. The output signal may be configured to cause the communication interface 118 to send of an alert notification message indicating that the voltage exceeds the neutral threshold. This enables an engineer to be dispatched to fix the problem, to minimise any downtime. The details of how the message is sent may be as described in relation to block 804.

Additionally, or alternatively, block 820 can comprise transmitting an output signal to cause the disconnector 115 to electrically disconnect a load from the three-phase power source 1. For example, where the disconnector 115 is comprised in the meter 100, this can comprise causing the disconnector 115 to disconnect the output terminals of the meter 100 from the input terminals of the meter 100. All of the conductors L1, L2, L3, N, and E (if present) may be disconnected. They may be disconnected sequentially as described earlier. If the disconnector 115 is external, the output signal may cause the communication interface 118 to send a message controlling the disconnector 115.

In some examples, initiating the disconnection may be dependent on the time-of-exceedance of the neutral threshold T2. The disconnection may be after a predetermined number of seconds of exceedance. For example, the detection system 104 may comprise a timer configured to start upon initiation of exceedance of the relevant threshold, wherein the detection system 104 is configured to initiate the disconnection in response to the timer reaching a predetermined time. The predetermined time may be no greater than one second. The predetermined time may be no less than 40 milliseconds. The predetermined time may be dependent on the voltage difference, for example: 70 v=5 sec or less, 200V=even less. Similar time-of-exceedance conditions may be implemented for any of the thresholds described herein.

As shown in FIG. 8, the method 800 can separately monitor the star-to-earth voltage. Decision block 812 comprises determining whether an earth warning condition is satisfied, associated with whatever the earth measuring conductor 134 is connected to, such as the local earth electrode 130.

Satisfaction of the earth warning condition depends on the voltage between the star point V_SP and the local earth electrode V_E rising towards an earth threshold. Block 812 may be performed by a controller 114 using the star-to-earth measuring circuitry 110.

For example, a lower threshold T3 than the earth threshold T4 may be set for this early warning, having a value at least 10 volts, or at least 20 volts below the earth threshold. The value is high enough to indicate a potential earthing problem before it becomes a full fault.

If the earth warning condition is satisfied, the method 800 proceeds to block 814 which comprises transmitting an output signal. Transmitting the output signal can comprise causing the communication interface 118 to send a warning notification message indicative of the satisfaction of the earth warning condition. The details of how the message is sent may be as described in relation to block 804.

Optionally, operations similar to blocks 812, 814 may be added as extra steps between blocks 804 and 806 to warn of a high voltage imbalance indicative of a possible neutral fault.

The next decision block 816 comprises determining whether the voltage difference between the star point V_SP and the local earth electrode V_E exceeds the earth threshold T4.

In an example implementation, the earth threshold is in the order of tens of volts, such as more than 30 volts or more than 40 volts. In an implementation, the earth threshold is approximately 70 volts. This has the same value as the neutral threshold, but could alternatively have a different value (e.g., up to 20 volts apart). The specific threshold values may vary from country to country/grid to grid.

In some examples, initiating the disconnection may be dependent on the time-of-exceedance of the earth threshold.

If block 816 is satisfied, the method 800 proceeds to block 820 as described above. Any resulting message may indicate the reason: earth fault or neutral fault, depending on which threshold was exceeded.

Depending on the implementation, a neutral fault could cause automatic disconnection whereas an earth fault could cause sending of an alert without automatic disconnection, or vice versa. Alternatively, either type of fault could cause the same results (both alerts, or both disconnection).

FIG. 11 illustrates a flowchart of a frequency measuring method 900. The method 900 provides a form of demand response, enabling loads to be introduced or paused dependent on whether the electrical grid is overloaded or under-capacity. The meter 100 therefore has a stabilizing effect on the grid.

The method 900 may be implemented by the meter 100. Decision block 902 comprises the detection system 104 measuring a frequency f_M of at least one of the phases, and determining whether the frequency exceeds an upper frequency threshold f_U greater than a nominal grid frequency and/or passes below a lower frequency threshold f_L less than the nominal grid frequency. For example, the decision block 902 may monitor whether the frequency of the phase is within an acceptable range of a target nominal grid frequency, such as plus or minus 3 Hz, or plus or minus 0.5 Hz. The target nominal grid frequency may be whatever is mandated for the country or region, such as 50 Hz or 60 Hz.

If decision block 902 is satisfied (frequency outside range), the method 900 proceeds to block 904. Block 904 comprises the detection system 104 transmitting an output signal.

In some examples, the output signal is configured to cause the communication interface 118 to send a frequency excursion notification message indicating that a frequency excursion has occurred. This prompts an operator to disconnect, reconnect, or modify the power of loads in a manner that stabilizes the grid frequency. When the frequency is too high, an increase in load helps to lower the frequency. If the frequency is too low, the load can be decreased to raise the frequency. The details of how the message is sent may be as described in relation to block 804.

If the method 900 is automatic, block 904 can comprise transmitting an output signal to a load control device to cause control of a load connected to the monitored phase, to connect, disconnect, or modify a power of the load, in the manner that stabilizes the grid frequency. For example, the output signal may be transmitted to a load control device in the form of a switching system as described above, and/or in the form of a load controller that controls a power level/duty cycle of the load.

In some examples, the method 900 may be performed continuously and separately for each phase L1, L2, L3. In a system comprising a plurality of meters 100, 100B, different meters may monitor different phases and/or different numbers of phases.

It would be useful if the various thresholds described above could be modified, especially the warnings and notifications associated with blocks 804 and 814. The customer, or an authorised engineer, may be provided with an application programming interface at their client device 500, enabling them to reconfigure a configuration setting for the meter 100 remotely. A reconfiguration signal may be received via the communication interface 118.

Alternatively, the meter 100 itself may comprise a human-machine interface enabling local reconfiguration.

In examples, configuration settings of a meter 100 may be modified to provide any one or more of the following:
a modified threshold to change any one or more of the thresholds/ranges described herein (T1, T2, T3, T4);
an output signal scheme controlling whether a disconnector 115 is controlled or whether a message is sent, or both, by any one or more of blocks 804, 814, 820, 904;
a disconnection scheme controlling which loads are disconnected by the disconnector 115/switching system in any one of blocks 804, 820, 904;
a phase transfer scheme controlling which phases the switching system can transfer the load between, in block 804; or
demand response conditions associated with block 904, such as rules governing how long a load can be disconnected for.

When a changed configuration setting has been requested, the detection system 104 may receive a signal, such as a threshold modification operation signal, via the communication interface 118. The detection system 104 may update its stored configuration settings in accordance with the requested changes.

In summary, the preceding description describes a three-phase meter 100 which has been modified to include an integrated star point 127 derived from the three phases L1, L2, L3, via a resistor or transformer network. The star point voltage V_SP will then replicate the utility (supply side) star point voltage, being very close to Earth potential or zero volts. Alternatively, the star point voltage can be derived by software calculation, comprising measuring the voltage on all phases L1, L2, L3, and calculating the star point 127 through software.

The meter 100 will then measure internally the voltage between the utility neutral conductor N and the newly created star point 127 (physically or calculated). This reference voltage will alert an open neutral from the utility and also any open neutrals downstream. For instance, if the meter 100 is installed next to a consumer unit (distribution board 200), then the meter 100 will detect if the connected neutral is loose and will send an alert signal via a server 400 (e.g., cloud server) to any desired recipient. This will act as a potential electrical fire prevention device.

If multiple devices are installed into a building, then they can all be networked together. This method of operation will detect open neutral on the network and open neutrals on individual sub-distribution boards/branch circuits.

A further feature is to measure the newly created star point 127 as an energy saving opportunity. If the star-to-neutral voltage reaches a certain threshold such as 5 volts, then this will indicate that the phases are not in a balanced state. Therefore, the device can send a report to any appointed recipient, giving the recipient the opportunity to reduce loads on phases or transfer loads between phases until the star point to neutral voltage reaches equilibrium (0 volts).

The meter 100 can either send the warning signal via the cloud, SMS, or any other appropriate communication protocol. In some examples, the meter 100 can have a switched output (disconnector 115) to bring in loads or take out loads.

The meter 100 can be further improved by frequency measuring, wherein loads can be introduced or paused dependant on whether the grid is being overloaded or under-capacity.

References to ‘computer-readable storage medium’, ‘computer program product’, ‘tangibly embodied computer program’ etc. or a ‘controller’, ‘computer’, ‘processor’ etc. should be understood to encompass not only computers having different architectures such as single/multi-processor architectures and sequential (Von Neumann)/parallel architectures but also specialized circuits such as field-programmable gate arrays (FPGA), application specific circuits (ASIC), signal processing devices and other processing circuitry. References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

As illustrated in FIG. 5, the computer program 406 may arrive at the meter 100 or controller via any suitable delivery mechanism 500. The delivery mechanism 500 may be, for example, a machine readable medium, a computer-readable medium, a non-transitory computer-readable storage medium, a computer program product, a memory device, a record medium such as a Compact Disc Read-Only Memory (CD-ROM) or a Digital Versatile Disc (DVD) or a solid-state memory, an article of manufacture that comprises or tangibly embodies the computer program 406.

The blocks illustrated in the FIGS. 10-11 may represent steps in a method and/or sections of code in the computer program 406. The illustration of a particular order to the blocks does not necessarily imply that there is a required or preferred order for the blocks and the order and arrangement of the block may be varied. Furthermore, it may be possible for some steps to be omitted.

Although embodiments of the present invention have been described in the preceding paragraphs with reference to various examples, it should be appreciated that modifications to the examples given can be made without departing from the scope of the invention as claimed. For example, the power source may be two-phase.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

I/We claim:

1. An electric meter comprising a metering engine to detect electrical energy consumption, and comprising a detection system, wherein the detection system is configured to:
create a star point from phases from a multi-phase power source;
measure a voltage between the star point and a neutral conductor or an earth conductor; and
transmit an output signal in dependence on the voltage exceeding a threshold.

2. The electric meter of claim 1, wherein the output signal is configured to cause at least one of:
sending of an alert notification message indicating that the voltage exceeds the threshold; or
causing a disconnector to electrically disconnect a load from the multi-phase power source in dependence on the voltage exceeding the threshold.

3. (canceled)

4. The electric meter of claim 3, wherein the output signal is configured to cause the disconnector to initiate phase disconnection prior to earth disconnection.

5. The electric meter of claim 1, wherein the output signal is a first output signal, wherein the detection system comprises frequency measuring circuitry configured to measure a frequency of at least one of the phases, and wherein the detection system is configured to transmit a second output signal in dependence on the frequency exceeding an upper frequency threshold greater than a nominal grid frequency and/or in dependence on the frequency passing below a lower frequency threshold less than the nominal grid frequency.

6. The electric meter of claim 5, wherein the upper frequency threshold has a value no more than 3 Hz above the nominal grid frequency, and wherein the lower frequency threshold has a value no more than 3 Hz below the nominal grid frequency.

7. The electric meter of claim 5, wherein the second output signal is configured to cause sending of a frequency excursion notification message indicating that a frequency excursion has occurred.

8. The electric meter of claim 5, wherein the second output signal is configured to cause a load control device to control a load connected to the at least one of the phases.

9. The electric meter of claim 1, wherein the threshold is a first voltage threshold, and wherein the detection system is configured to transmit a further output signal in dependence on the voltage exceeding a second voltage threshold less than the first voltage threshold.

10. The electric meter of claim 9, wherein the second voltage threshold has a value selected from the range 3 volts to 10 volts.

11. The electric meter of claim 9, wherein the further output signal is configured to cause sending of a voltage imbalance notification message indicating a voltage imbalance associated with an uneven distribution of single-phase loads supplied by the multi-phase power source.

12. The electric meter of claim 9, wherein the further output signal is configured to cause control of individual ones of the single-phase loads, to modify relative loading between individual ones of the phases to reduce the voltage.

13. The electric meter of claim 1, wherein the voltage is between the star point and the neutral conductor, wherein the threshold is a neutral threshold, and wherein the detection system is further configured to:
measure a second voltage, between the star point and the earth conductor; and
transmit the output signal in dependence on the second voltage exceeding an earth threshold.

14. The electric meter of claim 1, wherein the detection system is configured to cause transmission of one or more warning notification messages in dependence on the voltage exceeding one or more warning thresholds below the threshold.

15. The electric meter of claim 1, comprising a meter display to display information dependent on the electrical energy consumption detected by the metering engine.

16. The electric meter of claim 1, comprising a communication interface, wherein the detection system is configured to cause the communication interface to send information dependent on the measured voltage between the star point and the neutral conductor or earth conductor.

17-20. (canceled)

21. The electric meter of claim 1, wherein the multi-phase power source is a three-phase power source, having three of the phrases, wherein the star point is created by the detection system connecting to each of the three phases, and tying the three phases together in a star configuration to define a virtual neutral, wherein the star point is at a centre point of the star configuration.

22. The electric meter of claim 1, wherein the threshold has a value in the order of tens of volts, optionally being approximately 70 volts.

23. The electric meter of claim 1, wherein the detection system is configured to initiate the transmission of the output signal in dependence on a time-of-exceedance of the threshold.

24. A system comprising a plurality of devices, each device having a detection system as defined in claim 1, and at least one of the devices being an electric meter as defined in claim 1, wherein an upstream device of the plurality of devices is upstream of a plurality of branch circuits, wherein downstream devices of the plurality of devices are in respective ones of the branch circuits, and wherein a destination and/or instruction of the output signal associated with each detection system is dependent on which one of the devices detects the voltage exceeding a threshold.

25. (canceled)

26. An electric meter comprising a metering engine to detect electrical energy consumption, and comprising a detection system, wherein the detection system is configured to:
tie together phase conductors from a power source, at a point;
measure a voltage between the point and a neutral conductor or an earth conductor; and
transmit an output signal in dependence on the voltage exceeding a threshold.
